(19) United States
(12) Patent Application Publication
(10) Pub. No.: US 2011/0058321 A1
(43) Pub. Date: Mar. 10, 2011

(54) SETTLEMENT TERMINAL AND CONTROL METHOD FOR THE SAME

(75) Inventor: Naoto Yoshizawa, Tokyo (JP)

(73) Assignee: TOSHIBA TEC KABUSHIKI KAISHA, Tokyo (JP)

(21) Appl. No.: 12/872,008

(22) Filed: Aug. 31, 2010

(30) Foreign Application Priority Data
Sep. 4, 2009 (JP) 2009-204881

(51) Int. Cl. H05K 5/00

(52) U.S. Cl. 361/679.01

(57) ABSTRACT

According to one embodiment, a settlement terminal includes a terminal body, an input unit, a cover member, an elevating unit, and a controller. The input unit is provided on the terminal body and for an operator to operate to input secret information. The cover member is shaped to cover at least both lateral sides of the input unit, as viewed from the side of the operator's standing position. The elevating unit moves the cover member up and down inside and outside the terminal body. The controller drives the elevating unit to move the cover member up to a periphery of the input unit from inside the terminal body, at least when processing involving input of the secret information is executed.

### CROSS-REFERENCE TO RELATED APPLICATIONS

This application is based upon and claims the benefit of priority from the prior Japanese Patent Application No. 2009-204881, filed on Sep. 4, 2009, the entire contents of which are incorporated herein by reference.

### FIELD

Embodiments described herein relate generally to a settlement terminal used for accounting at an article selling store or a service providing store, and a control method for the same.

### BACKGROUND

Recently, as a settlement system for commercial transactions, card settlement using a credit card or the like is broadly used instead of settlement by cash. With the use of card settlement, customers no longer need to carry cash and stores no longer need to prepare a large amount of small coins for change. Because of such advantages, card settlement is expected to be more widely used in the future.

However, despite the foregoing advantages, there is also a disadvantage that unauthorized use of cards by non-owners can occur. In view of this circumstance, input of authentication information that is set in advance for each card is required for settlement in order to guarantee security of cards. Normally, authentication information used in card settlement includes a personal identification number (PIN) of approximately four digits and is inputted by an operation of a numerical keypad provided on a customer side of a settlement terminal such as POS (point of sales) terminal or an operation of a PIN pad connected to the settlement terminal via a general-purpose interface.

There is a risk that, when inputting a PIN number in the card settlement, the PIN number might become known to people around the operator of the numerical keypad or PIN pad on the basis of the movement of the operator's fingers. Moreover, the operator might be concerned about the eyes of the people in the surroundings and might not be able to input the PIN number without anxiety. In view of this circumstance, several techniques for peep prevention in PIN number input are proposed. For example, JP-A-2001-109953 describes a settlement terminal on which a cover over a numerical keypad is provided in such a manner that the cover can open and close, in order to make it difficult to visually recognize the numerical keypad for PIN number input from the surroundings. This cover usually covers the entire numerical keypad to limit customer's operations. At the time of settlement, the cover is rotated upward or downward about its supporting shaft and thus surrounds the numerical keypad from above or below and on both lateral sides.

The cover provided on the settlement terminal described in JP-A-2001-109953 includes a flat plate which covers the numerical keypad and opens and closes in the direction of the customer's standing position. For accepting an operation of the numerical keypad, the flat plate stands still in the state of protruding toward the operator from the terminal body. Therefore, the operability and visibility of the numerical keypad covered by the cover is significantly lowered depending on the proper field of vision and standing position of the customer as the operator. For example, when the cover opens upward, it is more difficult for a taller operator to visually recognize the numerical keypad since the top surface of the cover becomes an obstacle. Also, irrespective of whether the cover opens upward or downward, a part of the cover protrudes toward the operator's standing position at least in certain timing during the opening. Therefore, the cover might contact and hurt the operator or the cover itself might be damaged. Moreover, when the cover protrudes toward the operator's standing position at the time of opening, the operator may have to move back in order to operate the numerical keypad.

In this manner, while the conventional settlement terminal is successful in enhancing security for secret information including PIN numbers, there is still room for improvement in operability of the secret information input interface and visibility from the operator.

In view of the foregoing circumstances, a settlement terminal is demanded which enables prevention of peeping of input contents from the surroundings while maintaining operability of an interface used to input secret information including PIN numbers and visibility from the operator.

### BRIEF DESCRIPTION OF THE DRAWINGS

FIG. 1 is a perspective view of appearance showing a settlement terminal according to a first embodiment, as viewed from the side of a salesclerk's standing position.

FIG. 2 is a perspective view of appearance showing the settlement terminal according to the first embodiment, as viewed from the side of a customer's standing position.

FIG. 3 is a perspective view of appearance where a cover member provided on the settlement terminal according to the first embodiment is moved up.

FIG. 4 is a block diagram showing a control circuit of the settlement terminal according to the first embodiment.

FIG. 5 shows an example of an input screen displayed on a customer-side display unit of the settlement terminal according to the first embodiment.

FIG. 6 is a flowchart showing the processing executed by a CPU in accounting using the settlement terminal according to the first embodiment.

FIG. 7 shows an example of the input screen displayed on the customer-side display unit of the settlement terminal according to a second embodiment.

### DETAILED DESCRIPTION

In general, according to one embodiment, a settlement terminal includes a terminal body, an input unit, a cover member, an elevating unit, and a controller. The input unit is provided on the terminal body and for an operator to operate to input secret information. The cover member is shaped to cover at least both lateral sides of the input unit, as viewed from the side of the operator's standing position. The elevating unit moves the cover member up and down inside and outside the terminal body. The controller drives the elevating unit to move the cover member up to a periphery of the input unit from inside the terminal body, at least when processing involving input of the secret information is executed.

### First Embodiment

A first embodiment will be described with reference to the drawings.

In this embodiment, a settlement terminal placed on a checkout counter in an article selling store such as a retail store or a service providing store such as an eating and drinking place is described as an example.

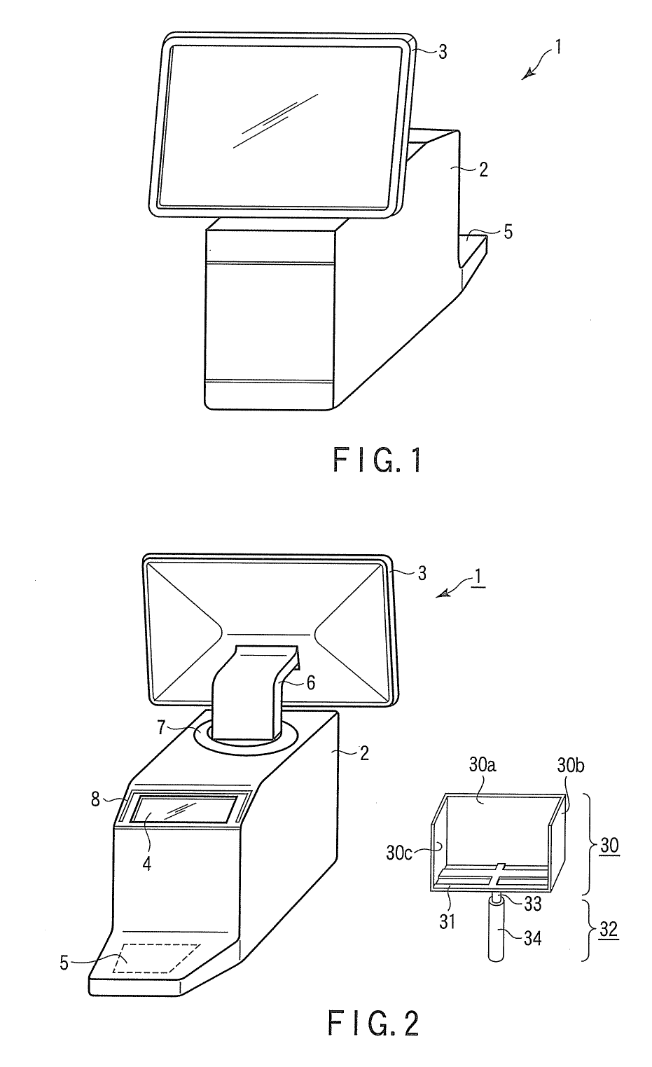

FIG. 1 is a perspective view of appearance showing a settlement terminal 1 according to this embodiment, as viewed from the side of the salesclerk's standing position. FIG. 2 is a perspective view of appearance showing the settlement terminal 1, as viewed from the side of the customer's standing position.

The settlement terminal 1 includes a body 2 and a display unit 3 attached to the body 2 via a bent elongate connection member 6.

The body 2 includes a customer-side display unit 4 (input unit) with a touch panel which is equipped with a control unit inside and is provided at an upper part on the side of the customer's standing position, and an electronic settlement unit 5 provided below the customer-side display unit 4.

The display unit 3 has a tilt mechanism, not shown, in a casing on the back side, and one end of the connection member 6 is attached to the display unit 3 via the tilt mechanism. The other end of the connection member 6 is attached to the body 2 via an attachment mechanism 7 provided on the top side of the body 2. The attachment mechanism 7 employs, for example, a swivel mechanism and fixes the connection member 6 in such a manner that the display unit 3 can freely turn horizontally with respect to the top side of the body 2.

The customer-side display unit 4 is fitted in the body 2, with the front side of its display surface inclined upward on the side of the customer's standing position. A slit 8 of a shape that is open to the side of the customer's standing position is provided around the customer-side display unit 4. Through this slit 8, a cover member 30 which is shown together with the settlement terminal 1 in FIG. 2 moves up and down. The cover member 30 has a folded-plate structure in which a flat plate 30a and flat plates 30b and 30c arranged to the left and right of the flat plate 30a are integrally formed. This cover member 30 is attached to a supporting plate 31. In order to achieve a peep prevention effect, the flat plates 30a, 30b and 30c are made of a material with translucency that is low enough to prevent at least clear visual recognition of the facing side.

Below the supporting plate 31, a hydraulic elevating unit 32 is attached which includes a rod 33 fixed to the supporting 31, a cylinder 34 supporting the rod 33 in such a manner that the rod 33 can freely appear and disappear, and a pump (not shown) which supplies oil to the cylinder 34. This elevating unit 32 drives the pump to adjust the pressure of oil within the cylinder 34 and thus moves the rod 33 or the cover member 30 up and down in a direction substantially perpendicular to the installation surface of the settlement terminal 1. Therefore, in any process of moving the cover member 30 up and down, the cover member 30 does not protrude toward the operator side from the lateral sides of the body 2 or lines extended from the lateral sides, on the side of the standing position of the customer as the operator of the customer-side display unit 4.

The upper sides of the flat plates 30b and 30c are processed in a sloped shape along the shape of the casing part where the slit 8 is provided. When the cover member 30 is moved down, the upper surface of the cover member 30 housed in the slit 8 is flush with the casing surface around the slit 8.

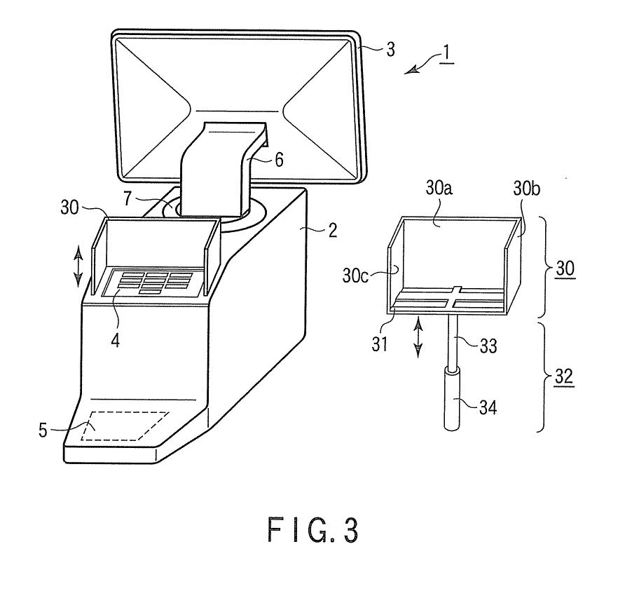

When the cover member 30 is moved up, the periphery of the customer-side display unit 4 is surrounded by the flat plates 30a, 30b and 30c in the state where the side of the standing position of the customer as the operator and the upper side are left open, as shown in FIG. 3. Therefore, the customer as the operator can visually recognize the vicinity of the display screen of the customer-side display unit 4 irrespective of whether the cover member 30 is moved up or down. However, when the cover member 30 is moved up, it is difficult for other people than the customer as the operator to visually recognize the vicinity of the display screen of the customer-side display unit 4.

Next, a control circuit of the settlement terminal 1 will be described.

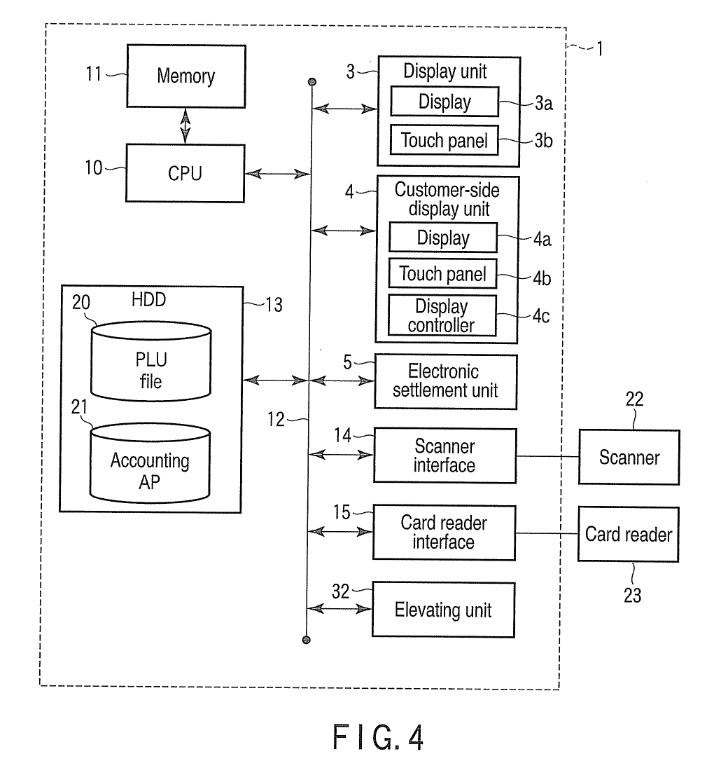

FIG. 4 is a block diagram showing the control circuit of the settlement terminal 1. On a mother board loaded within the body 2, a CPU (central processing unit) 10 functioning as a control center, and a memory 11 including a ROM (read only memory) and RAM (random access memory) are installed. A bus line 12 such as address bus or data bus is connected to the CPU 10 via a chip set, not shown. An HDD (hard disk drive) 13, a display 3a and a touch panel 3b of the display unit 3, a display 4a, a touch panel 4b and a display controller 4c of the customer-side display unit 4, the electronic settlement unit 5, a scanner interface 14, a card reader interface 15, and the elevating unit 32 are connected to the bus line 12.

In this embodiment, the CPU 10 functions as a controller which drives the elevating unit 32 to move the cover member 30 up and down.

The memory 11 forms various work memory areas according to processing situations. Particularly, when an accounting application 21, which will be described later, is executed, the memory 11 forms a work memory area to register article data on an article for which a PLU (price lookup) code is inputted.

The HDD 13 stores a database such as a PLU file 20 and an application file such as the accounting application (AP) 21. The PLU file 20 stores article data including the name and unit price of each article in association with the PLU code allocated to each article. The accounting application 21 is an application to carry out a series of accounting processes.

The display 3a of the display unit 3 is a display such as LCD (liquid crystal display), CRT (cathode ray tube) or OEL (organic electro-luminescence). The display 3a selectively displays an application screen, article data of a registered article, or information such as the total amount in a transaction in response to a command from the CPU 10.

The display 4a of the customer-side display unit 4 is a display such as LCD, CRT or OEL, similarly to the display 3a of the display unit 3. The display 4a selectively displays the total amount in a transaction, article data of an article for which a PLU code is inputted, store or article advertisement information, or a PIN number (secret information) input screen in response to a command from the CPU 10.

The touch panel 3b of the display unit 3 and the touch panel 4b of the customer-side display unit 4 are, for example, resistive touch panels. A voltage drop occurs according to the position touched by the user with a finger or touch pen. The quantity of the voltage drop is detected and the coordinates of the touched position are calculated.

The display controller 4c lowers the brightness of the display 4a from a default value when the PIN number input screen is displayed on the display 4a of the customer-side display unit 4.

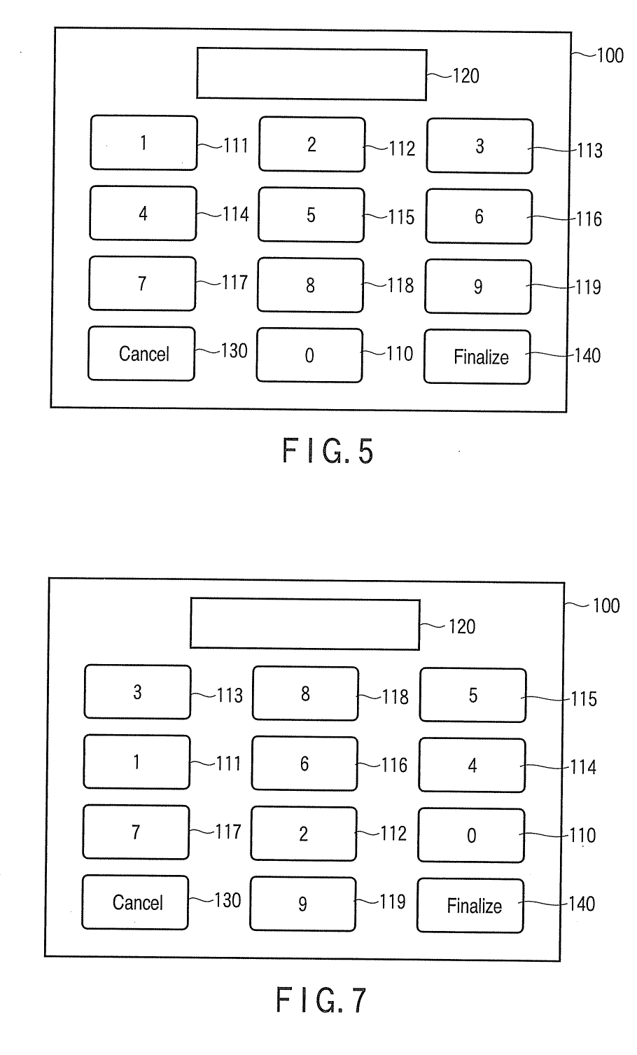

FIG. 5 shows an example of the PIN number input screen displayed on the display 4a of the customer-side display unit 4. This input screen 100 has a numerical keypad including numeric keys 110 to 119 to input numbers 0, 1, 2, . . . 9, a display area 120, a cancel key 130, and a finalize key 140. The keys are arranged in four rows with three keys each. That is, the numeric keys 111, 112 and 113 are arranged from left to right in the top row. The numeric keys 114, 115 and 116 are arranged from left to right in the second row. The numeric keys 117, 118 and 119 are arranged from left to right in the third row. The cancel key 130, the numeric key 110 and the finalize key 140 are arranged from left to right in the fourth row. In the input screen 100 with such a configuration, when a touch operation of the numeric keys 110 to 119 is detected by the touch panel 4b, the numbers corresponding to the operated keys are displayed in the display area 120. When a touch operation of the cancel key 130 is detected by the touch panel 4b, all the numbers displayed in the display area 120 are erased. When a touch operation of the finalize key 140 is detected by the touch panel 4b, the numbers displayed in the display area 120 are finalized as a PIN number. The CPU 10 is notified of the finalized PIN number.

The electronic settlement unit 5 has a wireless communication antenna, a transmission unit which transmits radio waves to an electronic money storage medium such as IC card or portable communication terminal via the antenna, and a receiving unit which demodulates response waves sent back from the electronic money storage medium in response to the radio waves transmitted from the transmission unit and thus acquires digital data of electronic money information. The CPU 10 is notified of the electronic money information acquired by the receiving unit.

The scanner interface 14 is connected to a scanner 22 as an external device. The scanner 22 optically scans the bar pattern of a barcode attached to an article or label and decodes the bar pattern into a PLU code. The CPU 10 is notified of the PLU code detected by the scanner 22, via the scanner interface 14.

The card reader interface 15 is connected to a card reader 23 as an external device. The card reader 23 reads card information from a card medium such as credit card or debit card and notifies the CPU 10 of the card information.

Next, the operation of the settlement terminal 1 with the above configuration will be described.

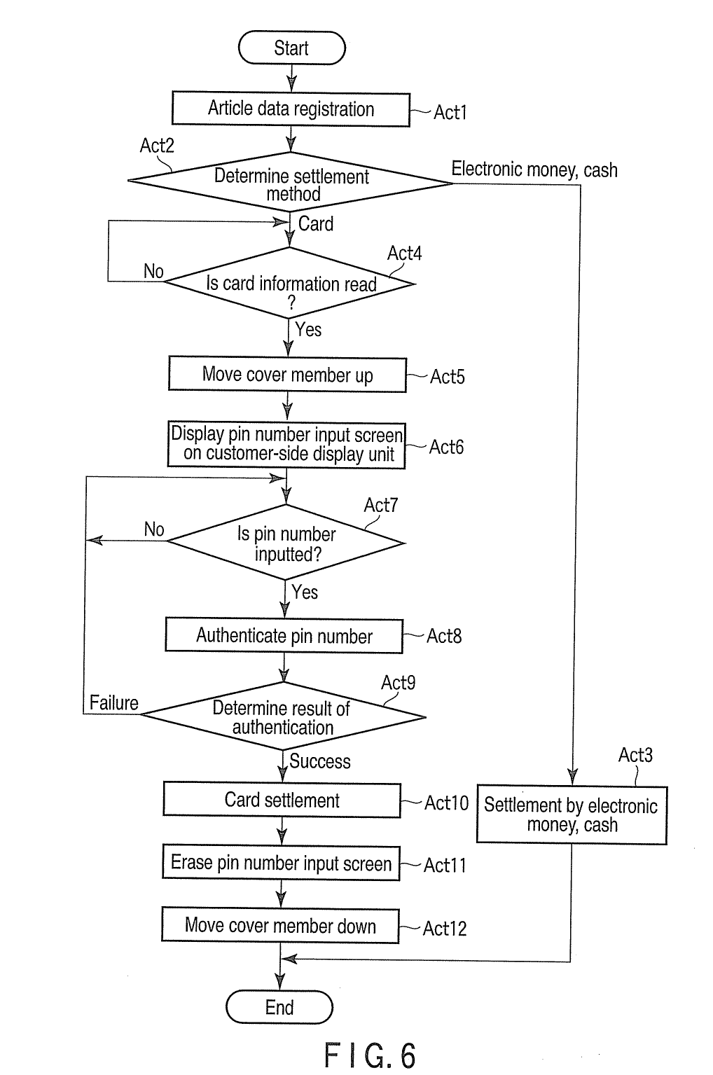

FIG. 6 is a flowchart showing the accounting executed on the accounting application 21. The start of this processing is triggered, for example, by the salesclerk's operation of a PLU key displayed on the display 3a of the display unit 3.

First, the CPU 10 executes article data registration (ACT 1). In this processing, the CPU 10 specifies article data stored in the PLU file 20 in association with a PLU code which the CPU 10 is notified of by the scanner 22, and registers the specified article data in the work memory area formed in the memory 11. During the execution of this processing, a subtotal key to declare the completion of the input of the PLU code is displayed on the display 3a of the display unit 3. When a touch operation of the subtotal key is detected by the touch panel 3b, the CPU 10 closes the registration of article data, calculates the price of the transaction based on the article data registered in the work memory area, and causes the display 3a of the display unit 3 and the display 4a of the customer-side display unit 4 to displace the price.

As the registration of article data is thus completed, the CPU 10 causes the display 3a of the display unit 3 to display a predetermined operation key and accepts the designation of a settlement method for the transaction (ACT 2). At this time, the salesclerk can designate which of electronic money settlement, cash settlement, and card settlement is to be used to receive the payment of the price by touch-operating the operation key displayed on the display unit 3.

When the touch operation of the operation key displayed on the display 3a is detected by the touch panel 3b and the operation designates electronic money settlement or cash settlement as the settlement method (“electronic money, cash” in ACT 2), the CPU 10 carries out electronic money settlement or cash settlement in accordance with the designation (ACT 3). That is, when electronic money settlement is designated as the settlement method, the CPU 10 shifts the electronic settlement unit 5 to a standby state for communication with the electronic money storage medium. In this case, when the electronic money storage medium is held over the electronic settlement unit 5, electronic money information is read from the medium and the CPU 10 is notified of the read electronic money information. The CPU 10 carries out electronic money settlement according to known procedures using the provided electronic money information. Meanwhile, when cash settlement is designated as the settlement method, the CPU 10 causes the display 3a of the display unit 3 to display the numerical keypad, then accepts the input of a deposit amount that is made by a touch operation of the numerical keypad, subtracts the price from the inputted amount and thus calculates the amount of change, and causes the display 3a of the display unit 3 and the display 4a of the customer-side display unit 4 to display the calculated amount of change. The CPU 10 also causes a receipt printer, not shown, which is connected to or built within the settlement terminal 1, to issue a receipt on which the details of the transaction are printed.

On the other hand, when the touch operation of the operation key displayed on the display 3a designates card settlement (“card” in ACT 2), the CPU 10 shifts the card reader 23 to a reading standby state via the card reader interface 15, then causes the display 4a of the customer-side display unit 4 to display a message prompting the reading of a credit card, and waits for the reading of card information by the card reader 23 (ACT 4). When card information is read from the credit card by the card reader 23 and the CPU 10 is notified of the card information (Yes in ACT 4), the CPU 10 drives the elevating unit 32 to move the cover member 30 up (ACT 5). After that, when the cover member 30 is completely moved up, the CPU 10 causes the display 4a of the customer-side display unit 4 to display the input screen 100 shown in FIG. 5 (ACT 6) and waits for the input of a PIN number (ACT 7). When displaying the input screen 100, the display controller 4c lowers the brightness of the display 4a of the customer-side display unit 4 from the normal level and thus reduces its visibility from the surroundings.

As described above, when the numeric keys 110 to 119 in the input screen 100 are touch-operated and the finalize key 140 is touch-operated in the state where numbers are inputted in the display area 120, the numbers inputted in the display area 120 are finalized as a PIN number. At this time, the CPU 10 transmits the PIN number to the online server of the credit card operator via a predetermined communication line in order to authorize the finalized PIN number (ACT 8). Then, the CPU 10 determines whether the authentication is done or not, on the basis of a response from the server (ACT 9). Consequently, when the authentication of the PIN number fails (“failure” in ACT 9), the CPU 10 causes the display 3a of the display unit 3 and the display 4a of the customer-side display unit 4 to display that the authentication is a failure and waits for the input of a PIN number again (ACT 7).

Meanwhile, when the authentication of the PIN number is successful (“success” in ACT 9), the CPU 10 executes card settlement using the card information that is read from the credit card (ACT 10). The CPU 10 then erases the input screen 100 displayed on the display 4a of the customer-side display unit 4 (ACT 11), drives the elevating unit 32 to move the cover member 30 down into the casing (ACT 12), and ends the accounting. When the input screen 100 is erased, the display controller 4c restores the brightness of the display 4a to the default level.

As described above, in the settlement terminal 1 according to this embodiment, when the input screen 100 to input a PIN number is displayed on the display 4a of the customer-side display unit 4, the cover member 30 is moved up to the periphery of the customer-side display unit 4. With such a configuration, when a customer inputs a PIN number, other customers waiting for their checkout and people standing around the settlement terminal 1 cannot visually recognize the input screen 100 easily. Moreover, the cover member 30 is moved up and down in such a manner that the cover member 30 does not protrude toward the operator side from the lateral sides of the body 2 or the lines extended form the lateral sides, on the side of the standing position of the operator of the customer-side display unit 4. Therefore, there is no risk that the cover member 30 might contact the customer or might be damaged.

The cover member 30 has a shape to surround the customer-side display unit 4 while leaving the operator side and the upper side of the input screen 100 open, when the cover member 30 is moved up to the periphery of the customer-side display unit 4. Thus, visual recognition of the display 4a of the customer-side display unit 4 is not prevented by the cover member 30, regardless of the position of the operator's eyes.

When the input screen 100 is not displayed on the customer-side display unit 4, the cover member 30 retreats into the casing of the body 2. Thus, when the display 4a is not used for the input of a PIN number, the visibility of the display 4a of the customer-side display unit 4 from the surroundings is not impaired. When the operator carries out an operation which causes no trouble or inconvenience even when visually recognized by people in the surroundings, the cover member 30 does not obstruct the operation, either.

### Second Embodiment

Next, a second embodiment will be described.

This embodiment is different from the first embodiment in that the display controller 4c of the customer-side display unit 4 changes the layout of the numeric keys included in the PIN number input screen displayed on the display 4a, every time the input screen is displayed. The same components as in the first embodiment are denoted by the same reference numerals and will not be described further in detail.

The accounting in this embodiment proceeds according to the flowchart shown in FIG. 6, as in the first embodiment. That is, when card settlement is designated as the settlement method (“card” in ACT 2) and card information is read (Yes in ACT 4), the cover member 30 moves up (ACT 5) and the input screen 100 having the numeric keys 110 to 119, the display area 120, the cancel key 130 and the finalize key 140 as shown in FIG. 5 is displayed on the display 4a of the customer-side display unit 4 (ACT 6).

However, when displaying the input screen 100 on the display 4a, the display controller 4c carries out processing to decide the layout of the numeric keys 110 to 119 included in the input screen 100. Then, the input screen 100 in which the numeric keys 110 to 119 are arranged according to the result of the processing is displayed on the display 4a.

This processing uses, for example, random numbers. That is, the display controller 4c executes a random number generation program and thus generates random numbers, and decides the layout of the numeric keys 110 to 119 according to the generated random numbers. Various methods can be employed as the method to decide the layout of the numeric keys 110 to 119 according to random numbers. For example, a table prescribing information representing layouts of the numeric keys 110 to 119 to a predetermined number of sectioned numerical value ranges, and the table is stored in the memory 11 or the like. As information prescribed to a numerical value range to which the generated random numbers belong is specified from the table, the layout of the numeric keys 110 to 119 is decided.

Alternatively, the display controller 4c may be provided with the function of a counter and the value of the counter may be used instead of random numbers. Thus, the layout of the numeric keys 110 to 119 may be decided.

FIG. 7 shows an example of the input screen 100 displayed on the display 4a after the layout of the numeric keys 110 to 119 is thus decided. In this input screen 100, the keys are arranged in four rows with three keys each, as in the input screen shown in FIG. 5. However, as a result of the foregoing decision process, the numeric keys 113, 118 and 115 are arranged from left to right in the top row. The numeric keys 111, 116 and 114 are arranged from left to right in the second row. The numeric keys 117, 112 and 110 are arranged from left to right in the third row. The cancel key 130, the numeric key 119 and the finalize key 140 are arranged from left to right in the fourth row.

As described above, in the settlement terminal 1 according to this embodiment, the layout of the numeric keys 110 to 119 included in the input screen 110 is changed every time the input screen 100 is displayed on the display 4a. Thus, it is difficult to conjecture input contents on the basis of the movement of the finger operating the numeric keys 110 to 119. Therefore, peeping of PIN numbers can be prevented more securely.

As a matter of course, this embodiment has advantages similar to the advantages of the first embodiment.

### Modifications

In the above embodiments, the case where the cover member 30 is moved up when the input screen 100 to input a PIN number is displayed on the display 4a of the customer-side display unit 4, is described. However, the display content for the cover member 30 which should be moved up is not limited to the input screen 100. The cover member 30 may also be moved up when an input screen for secret information including a certain password or personal information is displayed on the display 4a.

In the first embodiment, a mechanical numerical keypad may be provided instead of the customer-side display unit 4, and the input of a PIN number may be accepted via this numerical keypad.

In the above embodiments, the hydraulic elevating unit 32 is used to move the cover member 30 up and down. However, the cover member 30 may be moved up and down using other types of elevating units. For example, a motor that can rotate forward and backward may be provided in the body 2 and the cover member 30 may be moved up and down using the rotary motion of the motor as a driving source.

In the above embodiments, the input screen 100 is displayed on the display 4a of the customer-side display unit 4 when the cover member 30 is completely moved up, and the cover member 30 is moved down after the input screen 100 is erased. However, the timing of moving the cover member 30 up and down can be appropriately changed in consideration of the circumstances of the store, the type of secret information, the secret information input process and the like. For example, when a series of processing operations include plural processes including the input of secret information, it is possible to move the cover member 30 up only at the time of inputting secret information and to move the cover member 30 down when the input of the secret information is completed.

In the above embodiments, the scanner interface 14 is connected to the scanner 22 and the card reader interface 15 is connected with the card reader 23. However, the scanner 22 and the card reader 23 may be provided on the terminal body, instead of being externally attached to the settlement terminal 1.

In the above embodiments, a predetermined operation key is displayed on the display 3a of the display unit 3 and the designation of a settlement method for a transaction is accepted (ACT 2). However, a similar operation key may be displayed on the display 4a of the customer-side display unit 4 and a settlement method may be designated by the customer's operation.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A settlement terminal comprising:
a terminal body;
an input unit which is provided on the terminal body and for an operator to operate to input secret information;
a cover member which covers at least both lateral sides of the input unit, as viewed from the side of the operator's standing position;
an elevating unit which moves the cover member up and down inside and outside the terminal body; and
a controller which drives the elevating unit to move the cover member up to a periphery of the input unit from inside the terminal body, at least when processing involving input of the secret information is executed.

2. The terminal of claim 1, wherein the cover member has a shape to surround the input unit while leaving the side of the operator's standing position and an upper side open.

3. The terminal of claim 1, wherein the elevating unit moves the cover member up and down in a direction substantially perpendicular to an installation surface of the terminal body.

4. The terminal of claim 1, wherein the controller drives the elevating unit to move the cover member down into a casing of the terminal body when the input of the secret information via the input unit is completed.

5. The terminal of claim 1, wherein the secret information is a personal identification number (PIN) for card settlement, and the input unit includes an operation key for numerical input.

6. The terminal of claim 1, wherein the input unit is a display with a touch panel which displays an input screen to input the secret information.

7. The terminal of claim 6, wherein the display displays the input screen after the controller drives the elevating unit to move the cover member up to a periphery.

8. The terminal of claim 6, further comprising a display controller which lowers brightness of the display when the input screen is displayed.

9. The terminal of claim 6, wherein the input screen has plural operation keys to input the secret information, and
the terminal further comprises a display controller which changes a layout of the plural operation keys every time the input screen is displayed on the display.

10. A control method for a settlement terminal including an input unit which is provided on a terminal body and for an operator to operate to input secret information, a cover member which covers at least both lateral sides of the input unit, as viewed from the side of the operator's standing position, and an elevating unit which moves the cover member up and down inside and outside the terminal body, the method comprising:
driving the elevating unit to move the cover member up to a periphery of the input unit from inside the terminal body, at least when processing involving input of the secret information is executed; and
driving the elevating unit to move the cover member down into a casing of the terminal body when the input of the secret information via the input unit is completed.
